(19) United States
(12) Patent Application Publication
(10) Pub. No.: US 2009/0034411 A1
(43) Pub. Date: Feb. 5, 2009

(54) AUTOMATED DIAGNOSTICS AND TROUBLESHOOTING MECHANISM FOR END-USERS AND TECHNICIANS

(75) Inventor: MARC R. BERNARD, Miramar, FL (US)

Correspondence Address: FITZPATRICK CELLA HARPER & SCINTO, 30 ROCKEFELLER PLAZA, NEW YORK, NY, 10112, US

(73) Assignee: TELLABS VIENNA INC., Naperville, IL (US)

(21) Appl. No.: 11/833,699

(22) Filed: Aug. 3, 2007

(51) Int. Cl. G01R 31/08

(52) U.S. Cl. 370/221

(57) ABSTRACT

A method, apparatus, system, and computer-readable program, for operating a communication network that supports a plurality of types of communication services, such as video, voice, and data services. According to an example embodiment of the invention, the method includes detecting an operating condition affecting any of the communication services within the network, and providing a notification of the operating condition, by way of at least one of the communication services not affected by the operating condition. This notification can be provided in response to a request from a network component or a user, or in response to the detection. The method enables end-users and technicians to troubleshoot service problems based on the notification, which can be forwarded via a service not affected by the condition.

### BACKGROUND OF THE INVENTION

1. Field of the Invention

The present invention relates generally to diagnostics and troubleshooting for optical network equipment, and, more particularly, to automated diagnostics and troubleshooting mechanisms usable by end-users and technicians.

2. Description of the Related Art

There is a growing demand in the industry to find a solution to transmit voice, data, or video from a headend to a subscriber's premises through a fiber optic network all the way into an individual home or business. Such fiber optic networks generally are referred to as fiber-to-the-home (FTTH), fiber-to-the-premises (FTTP), fiber-to-the-business (FTTB), fiber-to-the-node (FTTN), or fiber-to-the-curb (FTTC) networks and the like, depending on the specific application of interest. Such types of networks are also referred to herein generally as “FTTx networks”.

In a FTTx network, equipment at a headend or central office couples the FTTx to external services such as a Public Switched Telephone Network (PSTN) or an external network. Signals received from these services are converted into optical signals and are combined onto a single optical fiber at a plurality of wavelengths, with each wavelength defining a channel within the FTTx network.

In a FTTP network, the optical signals are transmitted through the FTTP network to an optical splitter that splits the optical signals and transmits the individual optical signals over a single optical fiber to a subscriber's premises. At the subscriber's premises, the optical signals are converted into electrical signals using an Optical Network Terminal (ONT). The ONT may split the resultant signals into separate services required by the subscriber such as computer networking (data), telephony and video.

In FTTC and FTTN networks, the optical signal is converted to an electrical signal by either an Optical Network Unit (ONU) (FTTC) or a Remote Terminal (RT) (FTTN), before being provided to a subscriber's premises.

A typical FTTx network often includes one or more Optical Line Terminals (OLTs) which each include one or more Passive Optical Network (PON) cards. Such a typical network is illustrated in FIG. 1. Each OLT typically is communicatively coupled to one or more ONTs (in the case of a FTTP network), or to one or more Optical Network Units (ONU) (in the case of a FTTC network), via an Optical Distribution Network (ODN). In a FTTP network the ONTs are communicatively coupled to customer premises equipment (CPE) used by end users (e.g., customers or subscribers) of network services. In a FTTC network, the ONU's are communicatively coupled to network terminals (NT), and the NTs are communicatively coupled to CPE. NTs can be, for example, digital subscriber line (DSL) modems, asynchronous DSL (ADSL) modems, very high speed DSL (VDSL) modems, or the like.

In a FTTN network, each OLT typically can be communicatively coupled to one or more RTs. The RTs are communicatively coupled to NTs that are communicatively coupled to CPE.

When end users experience problems with a network service, they typically attempt to diagnose the problems themselves by checking for faulty connections, evaluating the presence or absence of LED signals on equipment, and/or by consulting equipment manuals and the like. While sometimes users may be able to solve problems on their own without any assistance from the service provider, very often the users cannot do so, and thus they seek troubleshooting assistance from a service provider's customer service entity and/or field technicians. As can be appreciated, such assistance can be costly and inefficient to the service provider, particularly when truck-rolls are involved. Moreover, even in cases where a technician assists in troubleshooting a problem on-site, the technician may not be able to recognize the source of the problem and still may have to contact a network operations center in an attempt to do so.

It would be useful, therefore, to provide an improved technique which enables end-users to troubleshoot network service problems on their own, to thereby minimize customer service assistance and truck-rolls of service providers, and which also can be used by end-users and technicians alike to more efficiently diagnose network service problems and/or confirm that network services are functioning correctly upon initial installation.

### SUMMARY OF THE INVENTION

The foregoing and other limitations are overcome by a method for operating a communication network that supports a plurality of types of communication services, and by an apparatus, system (network), and computer-readable program, that operate in accordance with the method.

According to an example embodiment of the invention, the method includes detecting an operating condition (or conditions) affecting any of the communication services within the network, and providing a notification of the operating condition, by way of at least one of the communication services not affected by the operating condition(s). This notification can be provided, for example, in response to a request from a network component or a user, or in response to the detection. Also according to an example aspect of the invention, the notification is provided over a same communication interface or communication media as that through which the service affected by the operating condition is provided.

The communication services include, for example, a voice service, a data service, and a video service, although in other embodiments they may include other types of services as well, or less than that number of services. The network comprises a plurality of network nodes that can communicate with each other, such as an Element Management System (EMS), Optical Line Terminal(s) (OLTs), and Optical Network Terminals (ONTs). According to an example embodiment of the invention, the method further comprises determining which ones of the ONTs are affected by the operating condition(s), and the EMS provides the notification to at least one of the OLTs. Also in one example embodiment of the invention, the at least one OLT provides a further notification of the operating condition to at least one of the ONTs, and the method further comprises notifying a user of the operating condition(s).

In still another example embodiment of the invention, the method further comprises providing troubleshooting information relating to the operating condition.

In still a further example embodiment of the invention, a mechanism is provided by which the user can interact with a menu and troubleshooting guide that assists in troubleshooting network service problems.

### BRIEF DESCRIPTION OF THE DRAWINGS

FIG. 1 represents a conventional FTTx network.

FIG. 2 is a block diagram of a communication system 1 that is suitable for practicing this invention.

FIG. 3 is an architecture diagram of a data processing system in accordance with an example embodiment of the present invention.

FIG. 4 is a network diagram of an example passive optical network (PON), which may be a more detailed version of one or more of the networks of the system 1 of FIG. 2.

FIG. 5 is a flow diagram that illustrates a typical example procedure for addressing network service problems.

FIGS. 6-8 are flow diagrams that illustrate methods in accordance with an example embodiment of this invention, wherein FIGS. 6 and 7 depict procedures from the end-user side perspective, and FIG. 8 depicts a procedure from a network side perspective.

FIGS. 9 and 10 are user interfaces which can be employed to diagnose and/or troubleshoot network problems according to an example embodiment of the invention.

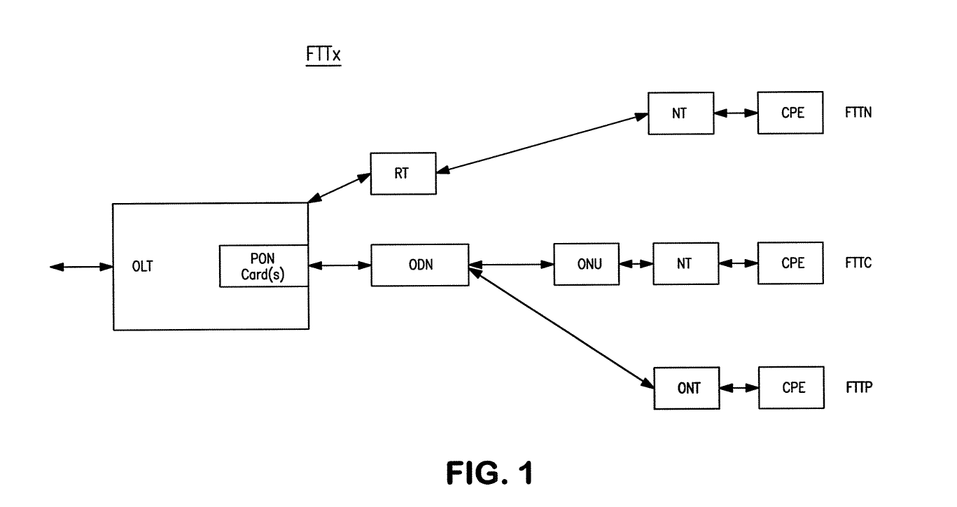

Reference numerals that are the same but which appear in different figures represent the same elements, even if those elements are not described with respect to each figure.

### DETAILED DESCRIPTION OF THE INVENTION

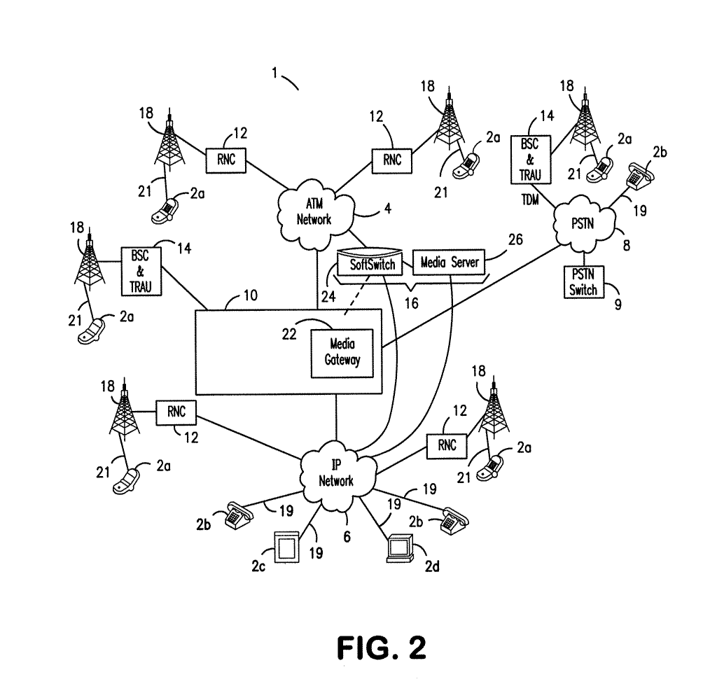

FIG. 2 is a block diagram of a communication system 1 that is suitable for practicing this invention. In the illustrated embodiment, the communication system 1 comprises customer premises equipment such as user communication terminals (devices) 2a, 2b, video devices 2c, computer terminals 2d, and also comprises a plurality of communication networks 4, 6, 8, a gateway 10, and various communication and/or control stations such as, for example, Radio Network Controllers (RNCs) 12, Base station Controllers (BSCs) and Transcoder Rate Adaptor Units (TRAUs), the latter two of which are shown and referred to hereinafter collectively as BSCs/TRAUs 14, base sites or base stations 18, and an Integrated Multimedia Server (IMS) 16. Traditionally, various types of interconnecting mechanisms may be employed for interconnecting the above components as shown in FIG. 2, such as, for example, optical fibers, wires, cables, switches, wireless interfaces, routers, modems, and/or other types of communication equipment, as can be readily appreciated by one skilled in the art, although, for convenience, no such mechanisms are explicitly identified in FIG. 2, besides wireless and wireline interfaces 21 and 19, respectively.

In the illustrated embodiment, the user communication terminals 2a are depicted as cellular radiotelephones that include an antenna for transmitting signals to and receiving signals from a base station 18 responsible for a given geographical cell, over a wireless interface 21.

The RNCs 12 are each communicatively coupled to a neighboring base station 18 and a corresponding network 4 or 6, and are capable of routing calls and messages to and from the user communication terminals 2a when the terminals are making and receiving calls. The RNCs 12 route such calls to the networks 6 and 4. The BSC portion of the BSCs/TRAUs 14 typically controls its neighboring base station 18 and controls the routing of calls and messages between terminals 2a and other components of the system 1 coupled bidirectionally to the respective BSC/TRAU 14, such as, for example, gateway 10 and network 8, and the TRAU portion of the BSCs/TRAUs 14 performs rate adaptation functions such as those defined in, for example, GSM recommendations 04.21 and 08.20 or later versions thereof. The base stations 18 typically have antennas to define their geographical coverage area.

According to the illustrated embodiment, network 8 is the PSTN that routes calls via one or more switches 9, the network 4 operates in accordance with Asynchronous Transfer Mode (ATM) technology, and the network 6 represents the Internet, adhering to TCP/IP protocols, although the present invention should not be construed as being limited for use only with one or more particular types of networks. Also, user communication terminals 2b are depicted as landline telephones, that are bidirectionally coupled to network 6 or 8.

It should be noted that although only the user communication terminals 2a, 2b, 2c, and 2d are shown in FIG. 2, any other suitable types of user communication terminals also may be employed, such as, for example, a portable PC docking node, a web TV, personal digital assistant, handheld personal digital assistant, palmtop computer, cellular radiotelephone, or pager, and the like. Moreover, the total number and variety of user communication terminals that may be included in the overall communication system in general can vary widely, depending on user support requirements, geographic locations, and applicable design/system operating criteria, etc., and are not limited to those depicted in FIG. 2. It should thus be clear that the teaching of this invention is not to be construed as being limited for use with any particular type of communication terminal. It also should be noted that the terms “communication terminal”, “user communication terminal”, and customer premises equipment” are used interchangeably herein.

The gateway 10 includes a media gateway 22 that acts as a translation unit between disparate telecommunications networks such as the networks 4, 6, and 8. Typically, media gateways are controlled by a media gateway controller, such as a call agent or a soft switch 24 which provides call control and signaling functionality, and enable multimedia communications across networks over multiple transport protocols, such as by providing conversions between TDM voice and Voice over Internet Protocol (VoIP), radio access networks of a public land network, and Next Generation Core Network technology, etc. Communication between media gateways and soft switches often is achieved by means of protocols such as, for example, MGCP, Megaco or SIP.

Media server 26 is a computer or farm of computers that facilitate the transmission, storage, and reception of information between different points, such as between networks (e.g., network 6) and soft switch 24 coupled thereto. From a hardware standpoint, a server 26 typically includes one or more components, such as one or more microprocessors (not shown in FIG. 2), for performing the arithmetic and/or logical operations required for program execution, and disk storage media, such as one or more disk drives (not shown in FIG. 2) for program and data storage, and a random access memory, for temporary data and program instruction storage. From a software standpoint, a server 26 typically includes server software resident on the disk storage media, which, when executed, directs the server 26 in performing transmission and reception functions. The server software runs on an operating system stored on the disk storage media, such as, for example, UNIX or Windows NT, and the operating system can adhere to TCP/IP protocols. As is well known in the art, server computers can run different operating systems, and can contain different types of server software, each type devoted to a different function, such as handling and managing data/information from a particular source, or transforming data/information from one format into another format. It should thus be clear that the teaching of this invention is not to be construed as being limited for use with any particular type of server computer, and that any other suitable type of device for facilitating the exchange and storage of information may be employed instead.

Although for convenience media server 26 is shown as being a single server, in other example embodiments server 26 may include plural separate servers, wherein each is dedicated to a separate application, such as, for example, a data application, a voice application, and a video application, although in other embodiments the functionality of those servers may be performed by a single server or by a combination of servers.

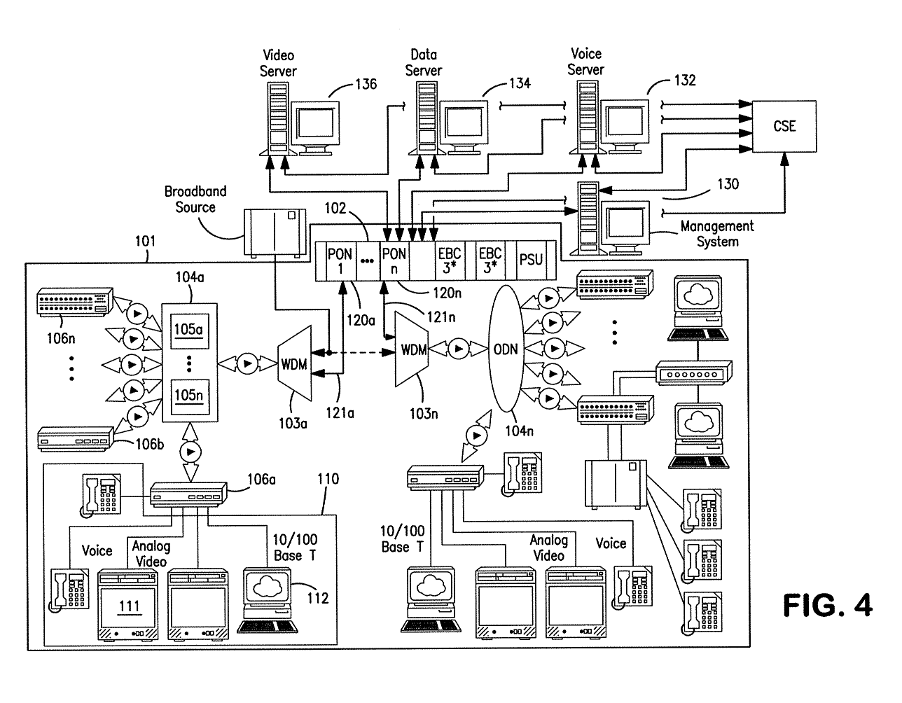

FIG. 4 is a network diagram of an example communication system or network, which may be a more detailed version of one or more of the networks of FIG. 2, such as, for example, network 6.

A Passive Optical Network (PON) 101 of the system includes an optical line terminal (OLT) 102, wavelength division multiplexers 103a-n, optical distribution network (ODN) devices 104a-n, ODN device splitters (e.g., 105a-n associated with ODN device 104a), optical network terminals (ONTs) (e.g., 106-n corresponding to ODN device splitters 105a-n), and customer premises equipment (e.g., 110). The OLT 102 includes PON cards 120a-n, each of which provides an optical feed (121a-n) to ODN devices 104a-n. Optical feed 121a, for example, is distributed through corresponding ODN device 104a by separate ODN device splitters 105a-n to respective ONTs 106a-n in order to provide communications to and from customer premises equipment 110.

The PON 101 may be deployed for fiber-to-the-business (FTTB), fiber-to-the-curb (FTTC), and fiber-to-the-home (FTTH) applications, for example. The optical feeds 121a-n in PON 101 may operate at bandwidths such as 155 Mb/sec, 622 Mb/sec, 1.25 Gb/sec, and 2.5 Gb/sec or any other desired bandwidth implementations. The PON 101 may incorporate, for example, ATM communications, broadband services such as Ethernet access and video distribution, Ethernet point-to-multipoint topologies, BPON communications, GPON communications, EPON communications, and native communications of data and time division multiplex (TDM) formats. Customer premises equipment (e.g., 110) which can receive and provide communications in the PON 101 may include standard telephones (e.g., Public Switched Telephone Network (PSTN)), Internet Protocol telephones, Ethernet units, video devices (e.g., 111), computer terminals (e.g., 112), any type of user communication device described above in connection with FIG. 2, digital subscriber line connections, cable modems, wireless access, as well as any other type of customer premise equipment.

PON 101 can include one or more different types of ONTs (e.g., 106a-n). Each ONT 106a-n, for example, communicates with an ODN device 104a through associated ODN device splitters 105a-n. Each ODN device 104a-n in turn communicates with an associated PON card 120a-n through respective wavelength division multiplexers 103a-n. Wavelength division multiplexers 103a-n are optional components which are used when video services are provided. Communications between the ODN devices 104a-n and the OLT 102 occur over a downstream wavelength and an upstream wavelength. The downstream communications from the OLT 102 to the ODN devices 104a-n may be provided at, for example, 622 megabytes per second, which is shared across all ONTs connected to the ODN devices 104a-n. The upstream communications from the ODN devices 104a-n to the PON cards 120a-n may be provided at, for example, 155 megabytes per second, which is shared among all ONTs connected to ODN devices 104a-n, although the invention is not limited to those specific types of downstream and upstream communications only, and may also include the types of example communications referred to above or any other suitable types of communications.

FIG. 4 further illustrates the OLT 102 managed by an element management system (EMS) 130. Since the OLT 102 includes the PON cards 120a-n, each PON card 120a-n is also managed by the EMS 130. As such, a single EMS manages all PON cards within a PON.

A single EMS, however, may manage or otherwise be associated with more than one PON. As such, a single EMS is not limited to managing PON cards within a single PON, but may manage PON cards from several PONs. In other embodiments, more than one EMS can be employed to manage one or more PON cards within a single PON or plural PONs.

FIG. 4 also illustrates plural servers, such as, for example a server 132 that supports voice applications, a server 134 that supports data applications, and a server 136 that supports video applications, although in other embodiments the functionality of those servers may be performed by only a single server or by a combination of servers. In still other example embodiments, the servers 132, 134, 136, and/or EMS 130 can be formed by a single server device or a combination of server devices, or no EMS 130 need be provided and the functionality of the EMS 130 can be provided by the servers 132, 134, and 136.

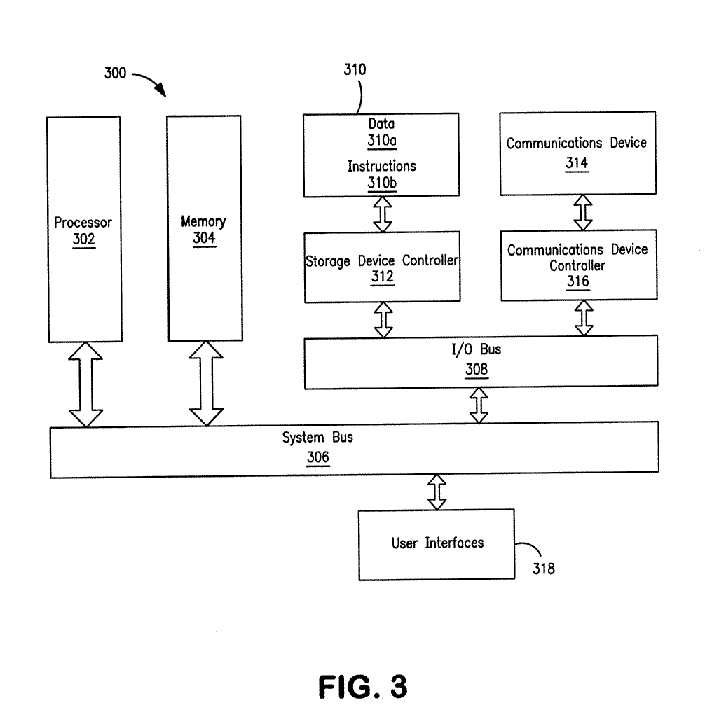

FIG. 3 is an architecture diagram of an example data processing system or device 300, which, according to an example embodiment, can form individual ones of the components 110, 130, 102, 104a-n, 106a-n, 132, 134, and 136 of FIG. 4. Data processing system 300 includes a processor 302 coupled to a memory 304 via system bus 306. Processor 302 is also coupled to external Input/Output (I/O) devices (not shown) via the system bus 306 and an I/O bus 308, and at least one input/output user interface 318. Processor 302 may be further coupled to a communications device 314 via a communications device controller 316 coupled to the I/O bus 308. Processor 302 uses the communications device 314 to communicate with a network, such as, for example, a network as shown in any of FIGS. 2 and 4, and the device 314 may have one or more input and output ports. Processor 302 also can include an internal clock (not shown) to keep track of time, periodic time intervals, and the like.

The input/output user interface 318 may include, for example, at least one of a keyboard, a mouse, a trackball, touch screen, a keypad, and/or any other suitable type of user-operable input device(s), and at least one of a video display, a liquid crystal or other flat panel display, a speaker, a printer, and/or any other suitable type of output device for enabling a user to perceive outputted information.

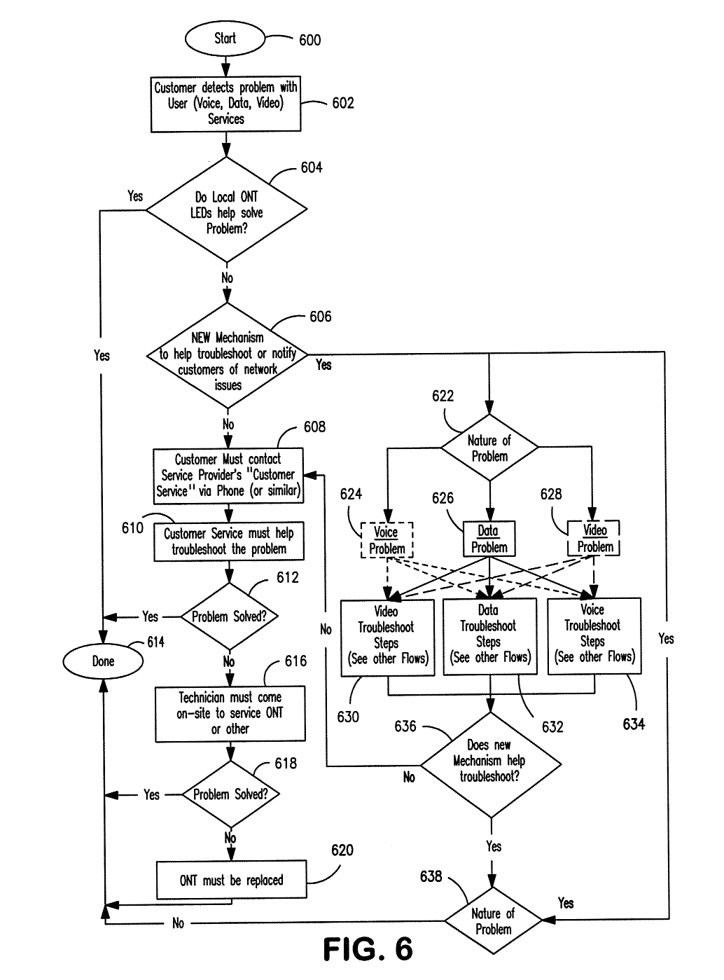

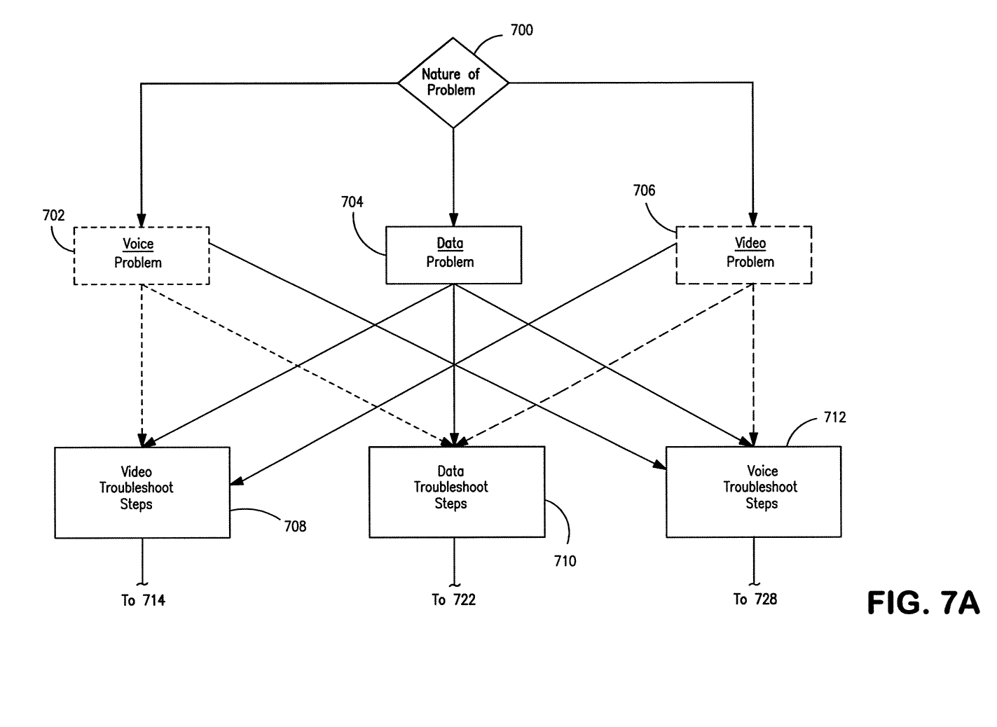

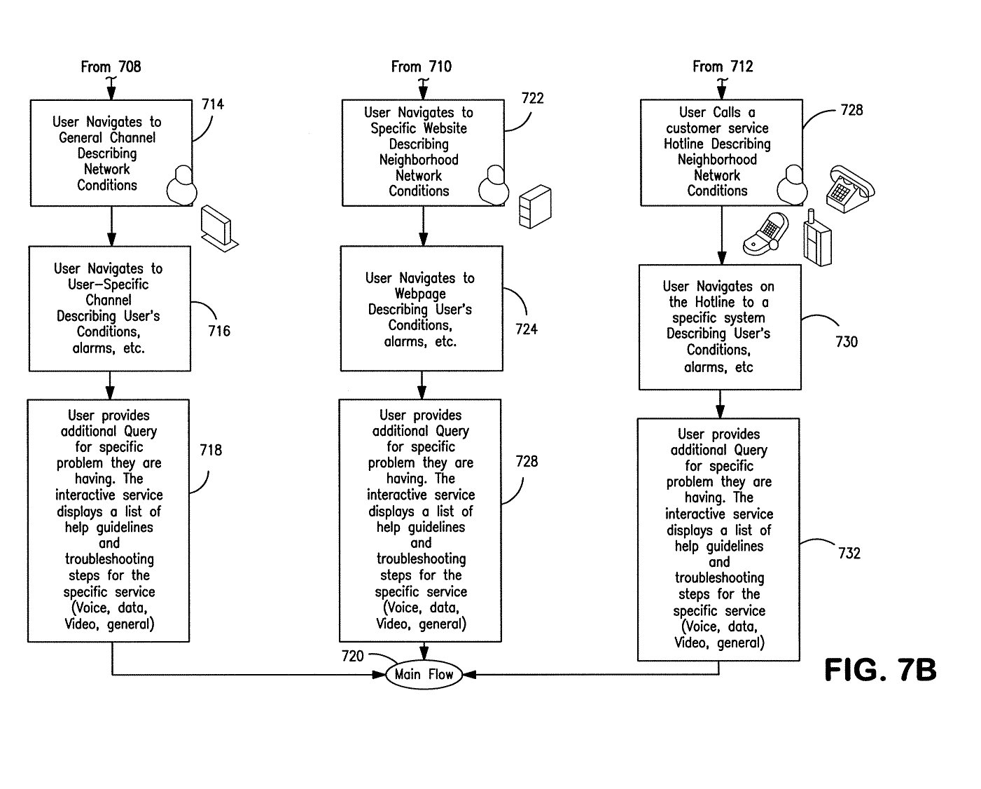

A storage device 310 having a computer-readable medium is coupled to the processor 302 via a storage device controller 312 and the I/O bus 308 and the system bus 306. The storage device 310 is used by the processor 302 and controller 312 to store and read/write data 310a, and to store program instructions 310b used to implement the procedures described below in connection with FIGS. 6, 7, and/or 8. The storage device 310 also stores various routines and operating programs (e.g., Microsoft Windows, UNIX/LINUX, or OS/2) that are used by the processor 302 for controlling the overall operation of the system 300. At least one of the programs (e.g., Microsoft Winsock) stored in storage device 310 can adhere to TCP/IP protocols (i.e., includes a TCP/IP stack), for implementing a known method for connecting to the Internet or another network, and may also include web browser software, such as, for example, Microsoft Internet Explorer (IE) and/or Netscape Navigator, for enabling a user of the system 300 to navigate or otherwise exchange information with the World Wide Web (WWW).

In operation, processor 302 loads the program instructions 310b from the storage device 310 into the memory 304. Processor 302 then executes the loaded program instructions 310b to perform any of the example methods described below, for operating the system 3 (which forms individual ones of the components 110, 130, 102, 104a-n, 106a-n, 132, 134, and 136).

In the case of at least the OLT 102 (and/or devices 130, 132, 134, 136), the storage device 310 also stores provisioning information and the like (e.g., Fault, Configuration, Accounting, Performance, Security (FCAPS) information) for the ONTs 106a-n or other devices associated therewith, and maintains records of general conditions of the network 101. Also, in the case of at least the ONTs 106a-n, devices 130, 132, 134, and 136, and/or OLT(s) 102, the instructions 310b stored in the storage device 310 also include instructions which, when executed by the processor 302, enable the detection of alarms and the like, and also enable such detections to be notified via the at least one input/output user interface 318 and forwarded via communications device 314 to another destination such as, for example, another OLT 102, ONT 106a-n, ODN 104, and/or device 130, 132, 134, 136. The instructions 310b also can enable the device 300 to request, receive and recognize the foregoing received detection notifications, originated from another device such as, e.g., ONTs 106a-n or another device, and to correlate any such notification information with the specific data, video, and/or voice channel(s) or the like for which the detection(s) were made.

In an example embodiment of the invention, alarms that are detected by an ONT 106a-n are collected by the ONT for any given interface thereof, such as interface(s) of device 314, although in other embodiments alarms can be detected by other network elements as well. Alarms can be detected in many different ways using known techniques. Depending on applicable operating criteria, in order for a condition to be deemed worthy of an alarm detection, it may be required for it to be present or consistent for a predetermined amount of time (e.g., 2.5 seconds) before the detecting network element declares an alarm and notifies other elements. Similarly, for clearing an alarm condition, the network element may be programmed to wait a predetermined time period (e.g., 10 seconds) during which the condition is no longer detected, before removing the alarm and notifying other network elements. In other example embodiments, no waiting period is required for either detecting or clearing an alarm, and the alarm is declared immediately upon detection and cleared immediately upon the alarm-causing condition ceasing to exist.

Alarms detected by an ONT 106a-n are sent upstream to the associated OLT 102. For example, this can be done using a standards-based communication interface such as the ONT Management Control Interface (OMCI), which is part of the G.983/G.984.x FTTP standards. The OLT 120 collects these alarms from all ONTs associated therewith, and may communicate them with some other device, such as the EMS 130 and/or devices 132, 134, 136, via, for example, SNMP, TL1, XML, and the like. Also in an example embodiment of the invention, the alarms can be collected and generated by each network element for all subtended interfaces and devices connected to the network elements, OLTs, ONTs etc.

According to another example embodiment of the invention, for one or more network elements such as, for example, the OLT 102 and/or devices 130, 132, 134, 136, 106a-n, the instructions 310b stored in the storage device 310 also include instructions which, when executed by the processor 302, perform one or more predetermined statistical regression analyses over one or more predetermined time periods, at predetermined times, or otherwise, based on collected and/or stored alarm information. The regression analyses, according to an example embodiment of the invention, may be implemented at a central location capable of monitoring many ONTs, such as at the EMS 130. The regression analyses can have, for example, an independent variable and multiple independent variables that can be used for determining if there are any predetermined types of relationships between detected alarm conditions. As a dependant variable, for example, the regression can have the number of detected alarm conditions or events associated with a given interface on the ONTs, and can have as independent variables, different predetermined characteristics of ONTs, such as, for example, the number of ports configured, the types of ONTs, different combinations of ports configured, the ages of the ONTs, the manufacturer, the services configured on the ONTs, etc. Upon running a regression analysis, if any of the factors associated with any of the independent variables are statistically significant with (e.g., meeting a predetermined (such as 95%) confidence interval), then it can be assumed that one or more of the given independent variables (e.g., the age of an ONT) will likely have a positive impact on the number of alarms (e.g., hardware failure, ONT loss-of-signal, or the like) declared by a given alarm. Information obtained using the regression analysis can then be translated into a format that is comprehendible for enabling recognition of one or more conditions associated with detected alarms, and customers can be notified. For example, the analysis may indicate that if ONTs are older than X years or have serial numbers corresponding to a specific age of the ONTs, then the ONTs must be replaced soon, although this is but merely one example provided for illustration purposes only. The information can be communicated to customers via, for example, cell phone, email, voice notification, or via another communication technique, as will be described further below.

Another, non-limiting example can be a power outage in a given neighborhood or geographical area. If the central system (e.g., EMS 130 or other network device) is able to detect any type of alarms that are associated with a power outage that is causing several customers to be without service for a certain amount of time, the system can either notify the customers via cell phone (call or text message) or some other communication technique so that the customers will be aware ahead of time. This can help alleviate the possibility that the service provider's customer service hotline will become overloaded with customer service calls and the like.

According to an example aspect of the invention, the storage device 310 of one or more of the devices 130, 132, 134, 136 also stores instructions 310b which enable the device to compile a history of detection notifications and correlations, and which enable the device 300 to provide information representing any such detection notifications, correlations, and history, to another device, such as, for example, another one of those devices, OLT(s) 102, ODN(s) 104a-n, ONT(s) 106a-n, customer premises equipment 110, or the like. In the case of servers 132, 134, and 136, any such information is stored in the storage device 310 thereof, and the instructions 310b also enable that information to be accessed or otherwise retrieved from the device by a remote network device, such as another server, OLT 102, EMS 130, ONT 106a-n, ODN 104a-n, or equipment 110. For example, that information may be accessed or retrieved from data server 134 through a URL (e.g., www.ONTstatus.com) associated with the server 134, and can then be presented at the requesting device over one or more web pages. In the case of video server 136, the information can be accessed or retrieved for presentation at the requesting device as video information over one or more predetermined channels, whereas in the case of voice server 132, the information can be accessed or retrieved for presentation as audible information at the requesting device, using, for example, a predetermined phone number or access code (e.g., 1-800-ONTDIAG). According to an example embodiment of the invention, the video information includes information about the general network status, broadcast over a general channel (e.g., analog), and information specific to one or more individual ONT(s) 106a-n and/or customer premises equipment 110, provided over a video channel dedicated therefor, such as an IPTV channel. In one example embodiment, video broadcast over a general channel presents a list of all ONTs 106a-n available in a user-selectable, interactive format, so that upon selection of one or more ONTs 106a-n listed by a user, the status of the selected ONT(s) is presented. For security purposes, such selections may require the entry of a specific access code, and/or a de-scrambling procedure may be provided based upon a specific key used at the retrieving device.

The instructions 310b stored the storage device 310 of at least one of the devices 130, 132, 134, 136, OLT 102, and/or ODN 104a-n also enable the device(s) to communicate with at least one soft switch (FIG. 2) and/or to provide at least one communication channel to at least one other switch (not shown), wherein in either case the at least one channel is accessible at other ones of the mentioned devices and/or ONTs 106a-n. Also according to an example aspect of the invention, when the video channel(s) or voice information or data are remotely accessed, the instructions 310b stored the storage device 310 of the devices 130, 132, 134, 136, OLT 102, and/or ODN 104a-n enable the accessing device(s) (e.g., ONTs) to retrieve network and/or device status information and/or troubleshooting information in, for example, an interactive menu format (e.g., voice, data, and/or video) depending on the type of service provided. That menu has a capability to enable selection of menu items and subsequent selections that guide a troubleshooter through automatic troubleshooting and/or diagnostics routines, and/or which enable a user to interact in real time or otherwise with a customer service entity (CSE) of the service provider, via the applicable devices 132, 134, 136, and/or 130. As but one non-limiting example of diagnostic routines that may be employed, an automated MLT Test procedure can be employed that automatically tests predetermined POTs interfaces and which can indicate whether one or more connections (e.g., RJ-11) to the relevant customer premises equipment 110 and/or wirings should be inspected and/or replaced. As another non-limiting example, automated traffic tests (e.g., ONT layer 2/3 tests), connectivity tests, video tests, etc., can be effected using the routines, and/or a guide can be provided which, based on prior knowledge about detected alarms and the like, identifies the types of problems which may be represented by particular types of indications (e.g., specific LED emissions) so that a user can troubleshoot problems based on the guide and conditions he or she may witness or be aware of. Also according to an example aspect of the invention, the devices 130, 132, 134, 136, 102, 104a-n, and/or 106a-n can ping one another and the equipment 110 and can automatically retrieve and display alarms, display provisioning information, display statistics, display historical log information relating to accessing and/or detections (any such features can be sold to subscribers separately or as part of the overall service(s) subscribed to).

According to an example embodiment of the invention, the network service provider can pre-configure alarms so that they are associated with specific actions. For example, the service provider may configure alarms A, B, C, etc. to be associated with actions X, Y, Z, etc., respectively, so that upon a network element such as the EMS 130 and/or OLT 102 detecting alarm A, the network element will respond by performing associated action X. As an example, alarm A may be pre-configured to be associated with problems with the video (or other service) head-end that provides RF video services, and the associated action may be to automatically notify all customers (via, e.g., another communication mechanism, such as a voice service (a call, text-message, or provide an automated 1-800 number which customers can call to find out about specific problems), a data service (e.g., a website accessible by one or more customers, email communication, etc.), or a video service (e.g., there may be a back-up head-end system that is used only to provide a video channel that provides up-to-date information about network conditions)). In still other example embodiments, the applicable network element(s) also may be programmed to dynamically learn other sophisticated conditions that can automatically determine that there are problems and automatically notify all (or one or more) customers involved. As but one example, a utility (or agent) that constantly performs regressions and correlations analyses on different criteria can be provided (e.g., at the EMS 130, one of the servers, or another network element), and, if it is detected statistically that significant criteria can be associated with a given network condition, the utility (or agent) can either immediately notify (via, e.g., components 110, 2a-2d) all affected customers or can first notify a technician who can further troubleshoot the problem before sending any notification(s) to end-users.

According to an example embodiment, only a predetermined sub-set of the foregoing types of the information referred to above (e.g., history of detection notifications and correlations, information representing detection notifications, correlations, and history, alarms etc.) can be accessed and presented at the equipment 110, ONTs 106a-n, ODN 104, and/or OLT 102, and in some example embodiments, the level and number of features that can be accessed and presented depends on, for example, the type of service provided and/or any predetermined agreement made by a service provider with applicable subscribers (e.g., a subscriber may pay for additional features). In still another example embodiment of the invention, the routines can provide an interactive service whereby an operator of, for example, equipment 110 can upgrade a particular service, enable/disable a particular service or feature (e.g., POTs, voice, video etc.) and the like. Also by example, the routines can enable the operator to reboot an associated ONT 106a-n in certain scenarios based on knowledge of types of detected alarms and the like, and/or knowledge of other ONTs 106a-n within the same network 101.

### Existing Troubleshooting

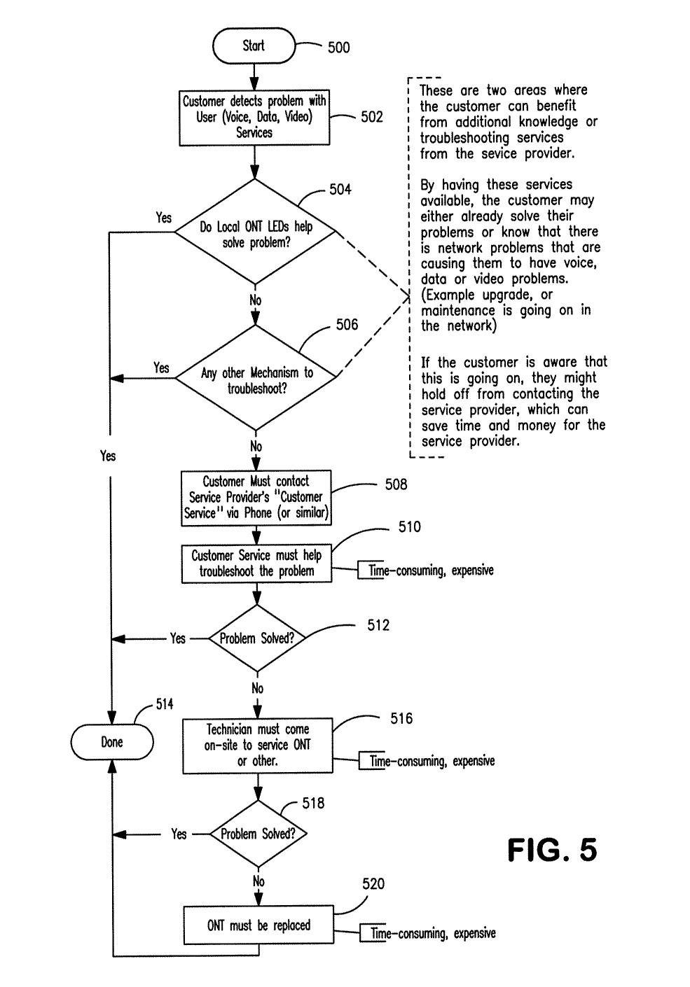

As described in the Background section above, when end users are experiencing problems with a network service, they typically request troubleshooting assistance from a service provider's customer service entity and/or field technicians. An example of a typical manner in which network service problems encountered by a customer are addressed will now be described, with reference to FIG. 5. Proceeding from block 500, subsequently at block 502 it is recognized that a communication problem exists, such as a problem with a network service such as voice, data, and/or video. For example, this recognition may include a user of equipment 110 detecting that a problem exists with one or more of those services.

Depending on the type of customer premises equipment 110 employed, and the services provided by the service provider, it may be possible for the user of the equipment 110 to determine and/or correct the problem without a need to contact the customer service entity of the service provider. For example, the local ONT 106a-n associated with the equipment 110 may have a capability of detecting and/or indicating the existence of a network problem (“Yes” at block 504) (e.g., faulty or missing batteries, hardware failures, loss of signal conditions for data interfaces, upgrade failure conditions, etc), such as by emitting a signal via one or more LEDs indicating the detected problem, and the user may be able to correct the problem such as by re-connecting an unintentionally disconnected cable, wire or the like. As another example, another mechanism may be provided by which the problem can be recognized and/or corrected (“Yes” at block 506). As an example, the user may know the source of the problem, such as by being aware that an upgrade or maintenance procedure is occurring in the network, or by virtue of another reason or mechanism. In either case the user may decide to forego contacting the service provider's customer service entity, which can save time and money for the user and the service provider. If “Yes” at either block 504 or block 506, then the procedure terminates at block 514.

If “No” at both blocks 504 and 506, then the user may elect to contact the service provider's customer service entity (block 508), via for example, telephone or another type of customer premises equipment 110, or any other way of communicating with the customer service entity. The customer service entity then assists in diagnosing, troubleshooting, and correcting the problem, if possible (block 510), which in some cases can be undesirably time consuming and expensive. If the problem then becomes corrected (“Yes” at block 512), then the procedure ends at block 514. Otherwise, if the problem is not solved (“No” at block 512), then a technician may come on-site to attempt to diagnose, troubleshoot, and correct the problem at the applicable ONT 106a-n, equipment 110, or at another network component (block 516), which also can be undesirably time consuming and expensive. If the problem then becomes corrected (“Yes” at block 518), then the procedure ends at block 514. Otherwise, if the problem is not solved (“No” at block 518), the technician may replace the equipment (e.g., ONT 106a-n, equipment 110, and/or another component) deemed to be not functioning correctly (block 520), which also can be undesirably time consuming and expensive. The procedure then ends (block 514).

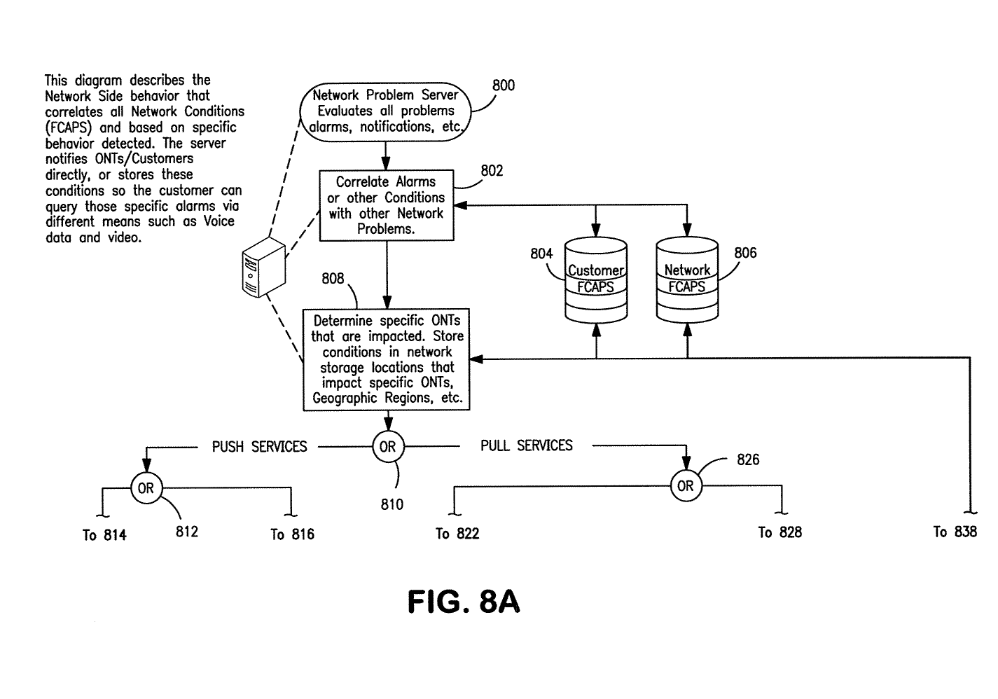

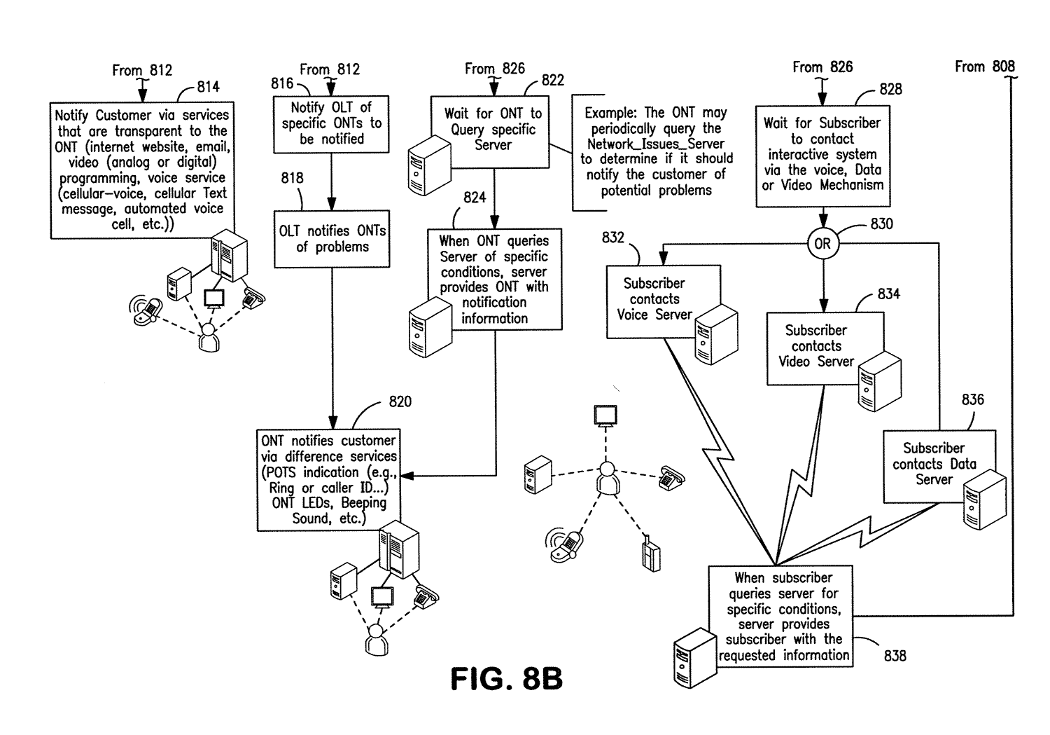

In view of the foregoing, it can be appreciated that the above conventional manner of addressing network service problems can be costly and inefficient, and that it would be useful to provide a more efficient, time- and cost-saving procedure for diagnosing and remedying network service problems. The inventors have discovered such a procedure, which will now be described in conjunction with FIGS. 6-8, wherein FIGS. 6 and 7 depict procedures from the perspective of the end user or customer side experiencing a network service problem, and FIG. 8 depicts a procedure from a network side perspective.

Troubleshooting at Customer End

FIG. 6 will first be described. At block 600 the method is started, and at block 602 it is recognized that a communication problem exists, such as a problem with a network service such as voice, data, and/or video. For example, this recognition may include a user of equipment 110 detecting that a problem with one or more of those services exists (i.e., the service is not being correctly received and/or is not otherwise functioning correctly).

Depending on the type of customer premises equipment 110 employed, and the services provided by the service provider, it may be possible for the user of the equipment 110 to determine and/or correct the problem without a need to contact the customer service entity of the service provider. For example, the local ONT 106a-n associated with the applicable equipment 110 may have a capability of detecting and/or indicating the existence of a network problem (“Yes” at block 604), such as by emitting a signal via one or more LEDs indicating the detected problem, or the like, and the user may then be able to correct the problem such as by re-connecting an unintentionally disconnected cable, wire or the like. As another example, another, inventive mechanism is provided by which the problem can be recognized and/or corrected (“Yes” at block 606), as will be described in detail below. Otherwise, if the user elects to forego employing that mechanism (“No” at block 606), then the user may elect to perform procedures at blocks 608-620 in the same manner as described above for blocks 508-520, respectively, of FIG. 5.

A situation where the user elects the inventive mechanism (“Yes” at block 606) to attempt to diagnose and/or troubleshoot the service problem(s) will now be described. Depending on the nature of the problem (block 622), one or more types of network services, such as, for example, a voice service (block 624), a data service (block 626), and/or a video service (block 628), may be affected over one or more applicable parts of the network. For example, the problems may be the result of network wide conditions that cannot be easily troubleshooted, such as, e.g., loss of video services within the headend, loss of voice services resulting from loss of a switch caused by maintenance, and/or loss of data, and may be caused by either a known or unknown event. Perhaps one or more fibers may have been cut in the network, and this is correlated by the OLT, or there is some possible network outage due to several alarms from a large number of ONTs within the network, or the like (of course, these examples are not exhaustive). As another example, the problem(s) may be specific to a particular network element such as an ONT. ONT-specific problems that typically might be troubleshooted locally by the user may include, for example, loss of service due to an Ethernet cable becoming de-coupled, bad or faulty wiring, or the like, and failure alarms may be declared in association with a bad or misbehaving ONT for failures, including for example battery failures, video connectivity problems, POTS/voice connectivity problems, and the like (of course, these examples also are not exhaustive). Such problems can be detected by, for example, one or more ONTs, OLTs, and/or other network elements (e.g., EMS 130 or other servers), as described above. In the case of any such problems at block 624, 626, and/or 628, the user may elect to troubleshoot the problem(s) using any one or more of a video troubleshooting procedure (block 630), a data troubleshooting procedure (block 632), and/or a voice troubleshooting procedure (block 634), depending on, for example, whether the related service(s) are functioning correctly. Those procedures will be described in more detail below.

After the performance of any such procedures, then, at block 636, a determination is made as to whether the procedure(s) successfully troubleshooted the applicable problem(s). For example, this determination may be made by the user recognizing the source of the problem(s) and/or that the applicable service(s) are now functioning correctly again, although the determination can be made in other suitable ways as well, such as automatically by applicable network elements (e.g., ONTs, CPEs and/or the like). If “No” at block 636, then the procedure returns to block 608 and proceeds in the above-described manner, whereas if “Yes” at block 636, control passes to block 638 where a determination is made as to whether another problem exists, such as another voice, data, and/or video service problem. If “Yes” at block 638, then the flow returns to block 606 where the method proceeds in the above-described manner, whereas if “No” at block 638, the flow passes to block 614 where the procedure ends.

FIG. 7 will now be described. In FIG. 7, blocks 700, 702, 704, and 706 are the same as blocks 622, 624, 626, and 628, respectively, of FIG. 6 described above. Also, blocks 708, 714, 716, and 718 show in greater detail the procedures of block 630 of FIG. 6, blocks 710, 722, 724, and 726 show in greater detail the procedures of block 632 of FIG. 6, and blocks 712, 728, 730, and 732 show in greater detail the procedures of block 634 of FIG. 6. As described above with respect to FIG. 6, regardless of the type of network service problem (i.e., a voice problem (block 702), data problem (block 704), or video problem (block 706)) being experienced, the user may elect to troubleshoot the problem using one or more of a video troubleshooting procedure (block 708), a data troubleshooting procedure (block 710), and/or a voice troubleshooting procedure (block 712), depending on which type of service remains functioning.

At block 708, a user may initiate video troubleshooting by operating customer premises equipment 110, such as, for example, a PC, television, another video device, or the like, to navigate to one or more predetermined video channels in an attempt to identify the cause of the problem(s). For example, the user can navigate to a predetermined general video channel (block 714) which, as described above, may be pre-designated to indicate general network conditions within a predetermined geographical area or in a predetermined part of the network. Such conditions can be obtained from, for example, video server 136, which maintains them in the above-described manner. The channel can, as described above, present a list of all or some ONTs 106a-n available in a user-selectable format, according to an example embodiment of the invention. Upon selection by a user of one or more ONTs 106a-n in the list using equipment 110, the status (including conditions) of the selected ONT(s) is presented. For security purposes, such selections may require the entry of a specific access code, and/or a de-scrambling procedure may be provided based upon a specific key used at the retrieving device.

As described above, the conditions may indicate an identifiable cause of the problem, such as a cable failure or the like. In one example embodiment of the invention, there is an interactive display capability provided that enables the user to interact with the user interface 318 of the customer premises equipment 110 to, for example, query the service provider's customer service entity (CSE) to obtain a customer service reply advising as to the cause of the problem or any known problems, and advising as to the expected time for removing the problem, or the like. Also, in at least one example, the video channel also provides information (e.g., in an interactive format) identifying that the user should take one or more courses of action to attempt to troubleshoot and/or correct the service problem. As but one example, the channel can display on the user interface 318 of the customer premises equipment 110 that the user should reboot the associated ONT 106a-n or the like, and can provide additional information in response to recognizing that the ONT 106a-n has been rebooted. As described above, such an interactive capability can be provided in real time or not in real time, depending on applicable operating criteria.

As another option, the user can navigate to another predetermined channel (block 716) (e.g., IPTV) which may be designated to represent network conditions specific to only one or more ONTs 106a-n, equipment 110, and/or other network devices, as described above. These conditions also may identify a cause of a problem, such as a cable failure and the like, either in the specific ONTs or equipment 110, or upstream (or elsewhere) in the network, and, in at least one example, the channel also provides information identifying that the user should take one or more courses of action to attempt to troubleshoot and/or correct the service problem. In one example embodiment of the invention, the channel can display that the user should reboot the associated ONT(s) or the like, and can provide additional information in response to recognizing that the ONT has been re-booted.

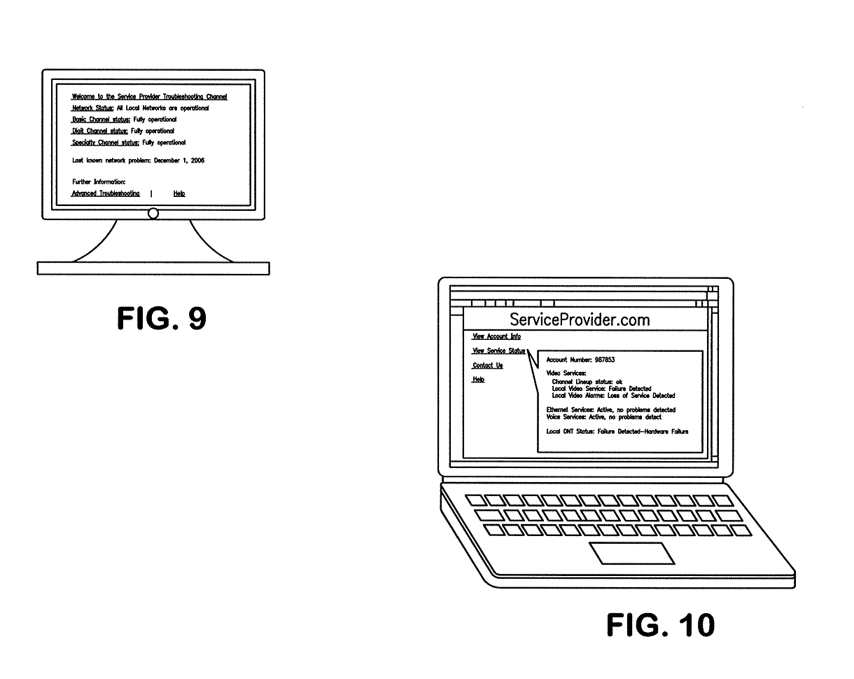

In either case of block 714 or 716, at block 718 the user can interact (e.g., through a presented menu format; see, e.g., FIG. 9)) with the information displayed over the channel at block 714 or 716, to conduct specific troubleshooting using presented help guidelines, troubleshooting steps, and the like for the specific type of service(s) (e.g., voice, data, video, general) experiencing the problem. By example only, the user can interact with the interactive capability provided at block 714 or 716 to, for example, query the service provider's customer service entity (CSE) to obtain a customer service reply advising as to the cause of the problem or any known problems, and advising as to the expected time for removing the problem, or the like. After the procedure is performed, at block 720 the main flow is returned to. For example, flow then proceeds to block 636 of FIG. 6.

The procedures of FIG. 7 corresponding to the block 632 of FIG. 6 will now be described in detail, according to an example embodiment of the invention. As described above, these procedures are performed in a case where the user elects to perform troubleshooting using a data troubleshooting procedure (block 710).

At block 710, the user may initiate this procedure by operating customer premises equipment 110, such as, for example, a PC or other data processing device, to navigate to one or more predetermined web pages in an attempt to view content (from, e.g., data server 134) identifying the cause of the problem(s). For example, the user can navigate to a predetermined web page (block 722) which may be pre-designated to indicate network conditions within a predetermined geographical area or in a predetermined part of the network. The conditions may indicate an identifiable cause of the problem, such as a cable failure or the like. In one example embodiment of the invention, as described above, one or more of the web pages provide an interactive capability that enables the user to interact with the page(s) via the user interface 318 of the customer premises equipment 110 to, for example, query the service provider's customer service entity (CSE) to obtain a customer service reply advising as to the cause of the problem or any known problems, and advising as to the expected time for removing the problem, or the like. Also, in at least one example, the web page(s) also provide information (e.g., in an interactive format) identifying that the user should take one or more courses of action to attempt to troubleshoot and/or correct the service problem. As but one example, the web page(s) can indicate that the user should reboot the associated ONT(s) 106a-n or the like, and can provide additional information in response to recognizing that the ONT 106a-n has been rebooted. As described above, such an interactive capability can be provided in real time or not in real time, depending on applicable operating criteria.

As another option, the user can navigate to one or more other predetermined web pages (block 724) which may be designated to represent network conditions specific to one or more ONTs 106a-n, equipment 110, and/or other network devices (see, e.g., FIG. 10). These conditions, which may be obtained from, e.g., data server 134 which maintains a record of them, also may identify a cause of a problem, such as a cable failure or the like, either in the specific ONT 106a-n or equipment 110, or upstream or elsewhere in the network, and, in at least one example, the page(s) also provide information identifying that the user should take one or more courses of action to attempt to troubleshoot and/or correct the service problem(s). In one example embodiment, the web page(s) can indicate that the user should reboot the associated ONT 106a-n or the like, and may provide additional information in response to recognizing that the ONT has been re-booted.

In either case of block 722 or 724, at block 726 the user can interact (via, for example, a presented menu format) with the information presented at block 722 or 724, to conduct specific troubleshooting using presented help guidelines, troubleshooting steps, and the like for the specific type of service(s) (e.g., voice, data, video, general) experiencing the problem. By example only, the user can interact with the interactive capability provided at block 722 or 724 to, for example, query the service provider's customer service entity (CSE) to obtain a customer service reply advising as to the cause of the problem or any known problems, and advising as to the expected time for removing the problem, or the like. After the procedures are performed, then at block 720 the main flow is returned to. For example, flow then proceeds back from block 636 of FIG. 6.

The procedures of FIG. 7 corresponding to the block 634 of FIG. 6 will now be described in detail, according to an example embodiment of the invention. As described above, these procedures are performed in a case where the user elects to perform troubleshooting using a voice troubleshooting procedure (block 712).

At block 712 the user may initiate this procedure by operating customer premises equipment 110, such as, for example, a telephony device or another voice communication device, to contact a customer service entity in an attempt to identify the cause of the problem(s). For example, the user can operate equipment 110 to call one or more predetermined access codes or phone numbers (block 728) (e.g., 1-800-ONTDIAG) to contact a customer service entity or other call center that may be pre-designated to indicate network conditions in a predetermined geographical area or in a predetermined part of the network. The conditions, which may be obtained from, e.g., a server such as voice server 132 which maintains them, may indicate an identifiable cause of the problem, such as a cable failure or the like, either in a specific ONT or elsewhere in the network 101. In one example embodiment of the invention, a voice interactive capability is provided that enables the user to interact therewith via the user interface 318 of the customer premises equipment 110 to, for example, query the service provider's customer service (CSE) to obtain an audible customer service reply advising as to the cause of the problem or any known problems, and advising as to the expected time for removing the problem, or the like. Also, in at least one example, the presented information identifies that the user should take one or more courses of action to attempt to troubleshoot and/or correct the service problem. As but one example, the information can indicate that the user should reboot the associated ONT 106a-n or the like, and can provide additional information in response to recognizing that the ONT 106a-n has been re-booted. As described above, such an interactive capability can be provided in real time or not in real time, depending on applicable operating criteria.

As another option, the user can call one or more other predetermined phone or access numbers (block 730) which may be designated to represent network conditions specific to one or more ONTs 106a-n, equipment 110, and/or other network devices. These conditions, which may be obtained from, e.g., a server such as server 132 which maintains a record of them, also may identify a cause of a problem, such as a cable failure or the like, either in the specific ONT 106a-n or equipment, or upstream or elsewhere in the network, and, in at least one example, information is provided that identifies that the user should take one or more courses of action to attempt to troubleshoot and/or correct the service problem(s). As but one example, the information can indicate that the user should reboot the associated ONT 106a-n or the like, and may provide additional information in response to recognizing that the ONT has been re-booted.

In either case of block 728 or 730, at block 732 the user can interact with the communication service at block 728 or 730, to conduct specific troubleshooting using presented help guidelines, troubleshooting steps, and the like for the specific type(s) of service(s) (e.g., voice, data, video, general) experiencing the problem. By example only, the user can interact with the interactive capability provided at block 728 or 730 to, for example, query the service provider's customer service entity (CSE) to obtain a customer service reply advising as to the cause of the problem or any known problems, and advising as to the expected time for removing the problem, or the like. After the procedures are performed, then at block 720 the main flow is returned to. For example, flow then proceeds back to block 636 of FIG. 6.

Troubleshooting in the Network

In accordance with another example aspect of the invention, one or more nodes in the network, such as the EMS 130 and/or servers 132, 134, 136, can correlate network conditions (FCAPS), and, based on the specific type(s) of behavior(s) detected, the node(s) notify other nodes (e.g., servers, ONTs, customer premises equipment, or the like), and can store a record of these conditions so that a user can query about specific alarms and network conditions using, for example, mechanisms such as one or more of the troubleshooting techniques described above. In other embodiments of the invention, other network nodes in addition to, or in lieu of, the devices 130, 132, 134, and 135 can perform such functions.

This aspect of the invention will now be described in detail with respect to FIG. 8. At block 800, the EMS 130 monitors for, detects, and evaluates any problems, alarms, notifications, and the like, that may be occurring in the network. This step may be performed in accordance with any suitable type of network management protocol, such as, for example, the (FCAPS) network management model of ISO, or any other suitable type of protocol, such as the Information Technology Infrastructure Library (ITIL), or the like. Block 800 may include the EMS 130 requesting status information from other nodes, such as OLT 102, ONT 106a-n etc., or they may notify the EMS 130 automatically or periodically. At block 802 the EMS 130 correlates any detected alarms and other conditions detected in block 800 with other network problems based on user FCAPS 804 and network FCAPS 806, respectively. Upon performance of block 802, the EMS 130 then determines the specific ONT(s), other network components, and the like, that are impacted by conditions such as problems, alarms, notifications, etc. (block 808) using the network management protocol, and, according to an example embodiment of the invention, the EMS 130 stores information representing both the detected conditions and those network components and geographic regions impacted thereby, in one or more predetermined network storage locations, such as in the device 310 of EMS 130, or at another storage location, whether associated with EMS 130, one or more servers 132, 134, 136, or otherwise. In one example embodiment of the invention, the EMS 130 also provides information indicating the detected conditions to other predetermined network components, such as, e.g., one or more servers 132, 134, 136, OLT(s) 120, ONT(s) 104a-n and/or other components that are affected by the conditions and/or located within one or more particular geographic regions, by way of services not affected by the conditions, although the invention is not limited to this example only. That information can be stored in a memory device 310 associated with those components for subsequent retrieval, such as in reply to a user request as described above in connection with FIG. 7, or automatically or periodically.

Regarding the regression analysis, in an example embodiment of the invention the analysis is performed by, for example, an agent task in an EMS 130, OLT 120, or manually by a technician able to manipulate data stored in the customer FCAPS 804 and network FCAPS 806. Blocks 804 and 806 (referred to above) contain all alarm provisioning information and historical performance monitoring information for all network elements in the network (e.g., customer components and network/OLT components), wherein that information can be obtained in the manner described above. According to an example embodiment of the invention, performance of block 802 includes taking all of this information and continuously determining if network problems that are present are related to other aspects of the network, in a manner as described above, for example. Block 808 referred to above can be performed by, for example, notifying certain customers via certain predetermined services (e.g., voice, data, or video) based on pre-known (pre-stored) customer preferences. For example, this can be via a push service or pull service (see the “OR” decision block 810), depending on applicable operating criteria. In the case of push services, for example, the EMS 130 (and/or servers 132, 134, 136) can notify a user via network services that can be transparent to the ONT(s) (block 814) by providing provisions and information which enable the troubleshooting procedures of blocks 708, 710, and 712 described above, to provide for such troubleshooting capabilities. This can include, for example, the EMS 130 generating one or more of information that is presented on one or more webpages, at least one email communication, video (analog or digital) programming, a voice service (e.g., cellular-voice, cellular text-message, an automated voice call, or the like), and can be performed by the EMS 130 alone or in conjunction with servers 132, 134, 136. These can be directed to components affected by the conditions. In a case in which a condition is causing a problem with a video service, for example, the EMS 130 can send, or direct server 132 and/or 134 to send, a voice (or other audible) message, email, or text (or other data) communication to ONT(s) 106a-n and/or equipment 110 associated therewith to notify of the problem. As another example, in a case in which a condition is causing a problem with a voice service, the EMS 130 can send, or direct the server 134 to send, an email or text (or other data) communication to ONT(s) 106a-n and/or equipment 110 associated therewith, or provide (or direct server 136 to provide) information on a predetermined video channel, to notify of the problem. Further by example, in a case in which a condition is causing a problem with a data service, the EMS 130 can send (or direct the server 132 to send) a voice (or other audible) communication to ONT(s) 106a-n and/or equipment 110 associated therewith, or provide (or direct the server 136 to provide) information on a predetermined video channel, to notify of the problem. Also in the case of push services (block 812), the EMS 130 can also or alternatively perform processing according to block 816 where the EMS 130 notifies the OLT(s) of the specific ONT(s) to be notified of the conditions (e.g., problems, notifications, alarms, and the like) that may be affecting the ONT(s). After block 816 is performed, then at block 818 the OLT(s) 102 notify the specific ONT(s) 106a-n of the conditions, and then, at block 820, the ONT(s) notify the user via one or more predetermined means of communication, such as by, for example, through a POTS indication (e.g., one or more predetermined ring tones, an indication via caller ID), activating one or more ONT LED(s), indicating one or more predetermined sounds, or otherwise communicating through customer premises equipment 110, or the like. In an example embodiment of the invention, the means of communication are via one or more services not affected by the problem condition, and/or over one or more communication interfaces/media (e.g., intermediate, connecting components of the network described above), although the invention is not limited to these example only.

In the case in which a pull service is performed, then the EMS 130 awaits for either ONT(s) 106a-n and/or OLT 102 to query the EMS 130 (or another predetermined server) (blocks 826 and 822), or for a user (subscriber) to initiate a query such as via, for example, an interactive voice, data, and/or video troubleshooting procedure (blocks 826 and 828), such as those described above in connection with blocks 708, 714-718, 710, 722-726, and 712, and 728-732 of FIG. 7.

As but one example of a case in which block 822 is performed, the ONT(s) 106a-n may query the OLT 102, EMS 130, and/or device 132, 134, 136 periodically to determine if the ONT(s) 106a-n should notify user(s) of potential problems. Upon the EMS 130 (or other server) being queried by an ONT and/or OLT, the EMS 130 (or server) provides the ONT with the notification information (block 824), such as, for example, information stored earlier in block 808 for that ONT. Thereafter, control passes to block 820 which is performed in the same manner as described above.

A case of a user-initiated query (blocks 826 and 828) will now be described. Such a query can be initiated in any suitable manner, such as, for example, by a user communicating with interactive voice server 132 (blocks 830 and 832), video server 136 (blocks 830 and 834), and/or a data server 134 (blocks 830 and 836) (see, e.g., FIG. 7), from one or more customer premises equipment 110. Such communication(s) also can be effected via any suitable communication technology, such as via a voice, data, and/or video communication mechanism, and can be effected by way of EMS 130, or by communicating directly with the servers 132, 134, 136. In response to any of blocks 832, 834, or 836 being performed, the EMS 130 (or other applicable server) provides the requested information to the requesting equipment 110 used by the user via the particular type of voice, video, and/or data service used in blocks 832, 834, and 836, respectively, or via another suitable communication mechanism. In an example embodiment of the invention, blocks 832 and 838 are performed in the manner described above with respect to blocks 728-832, blocks 834 and 838 are performed in the manner described above with respect to blocks 714-718, and blocks 836 and 838 are performed in the manner described above with respect to blocks 722-726.

By virtue of the example methods of the invention described herein, end users can be provided with an interactive troubleshooting mechanism available via, for example, voice, video (analog or digital), or data, and the end users can employ the mechanism to troubleshoot problems which may exist in the service(s) subscribed to by the users. Such users can employ this mechanism prior to, or to the exclusion of, contacting a customer service representative in an attempt to resolve the problem. The mechanism also can be useful for technicians and the like during, for example, installation or truck-rolls, to enable service problems to be evaluated. Technicians and/or users can perceive the provided status/provisioning information, alarms, and the like, and can access a craft port, which is an interface to manage a device such as an ONT. An example of a craft port that may be employed is described in U.S. Pat. No. 7,123,692 B2, which is hereby incorporated by reference as if fully set forth herein. Based on information provided at two end-points, the technician and/or user can determine whether or not there is a problem with a component such as an ONT or OLT. For example, if a video state is indicated as being “enabled” when status information is requested using the voice or data troubleshooting procedures, but a video port status is “disabled” when an ONT craft port is accessed, then there may be a provisioning issue. Using such knowledge, it can be easier to then troubleshoot a problem as compared to a case where the information is not available.

It should be noted that although the above description is described in the context of network status information being collected by the EMS 130 or another server, in other example embodiments the information also can be obtained directly from other components such as ONTs 106a-n. Also, although the example methods of the invention are described in the context of employing ONTs and OLTs, in other example embodiments the methods can be performed using ONUs, NTs, RTs, or the like.

In the foregoing description, the invention is described with reference to specific example embodiments thereof. The specification and drawings are accordingly to be regarded in an illustrative rather than in a restrictive sense. It will, however, be evident that various modifications and changes may be made thereto, in a computer program product or software, hardware, or any combination thereof, without departing from the broader spirit and scope of the present invention.

Software embodiments of the present invention may be provided as a computer program product, or software, that may include an article of manufacture on a machine accessible or machine readable medium (memory) having instructions. The instructions on the machine accessible or machine readable medium may be used to program a computer system or other electronic device. The machine-readable medium may include, but is not limited to, floppy diskettes, optical disks, CD-ROMs, and magneto-optical disks or other types of media/machine-readable medium suitable for storing or transmitting electronic instructions. The techniques described herein are not limited to any particular software configuration. They may find applicability in any computing or processing environment. The terms “machine accessible medium” or “machine readable medium” used herein shall include any medium that is capable of storing, encoding, or transmitting a sequence of instructions for execution by the machine and that cause the machine to perform any one of the methods described herein. Furthermore, it is common in the art to speak of software, in one form or another (e.g., program, procedure, process, application, module, unit, logic, and so on) as taking an action or causing a result. Such expressions are merely a shorthand way of stating that the execution of the software by a processing system causes the processor to perform an action to produce a result. In other embodiments, functions performed by software can instead be performed by hardcoded modules, and thus the invention is not limited only for use with stored software programs.

Although this invention has been described in certain specific embodiments, many additional modifications and variations would be apparent to those skilled in the art. It is therefore to be understood that this invention may be practiced otherwise than as specifically described. Thus, the present embodiments of the invention should be considered in all respects as illustrative and not restrictive.

In addition, it should be understood that the figures illustrated in the attachments, which highlight the functionality and advantages of the present invention, are presented for example purposes only. The architecture of the present invention is sufficiently flexible and configurable, such that it may be utilized (and navigated) in ways other than that shown in the accompanying figures.

Furthermore, the purpose of the foregoing Abstract is to enable the U.S. Patent and Trademark Office and the public generally, and especially the scientists, engineers and practitioners in the art who are not familiar with patent or legal terms or phraseology, to determine quickly from a cursory inspection the nature and essence of the technical disclosure of the application. The Abstract is not intended to be limiting as to the scope of the present invention in any way. It is also to be understood that the steps and processes recited in the claims need not be performed in the order presented.

What is claimed is:

1. A method for operating a communication network that supports a plurality of types of communication services, the method comprising:
detecting an operating condition affecting any of the communication services within the network; and
automatically providing a notification of the operating condition, by way of at least one of the communication services not affected by the operating condition.

2. A method as set forth in claim 1, wherein the network comprises a plurality of network nodes that can communicate with each other, and wherein the method further comprises determining which ones of the nodes are affected by the operating condition.

3. A method as set forth in claim 2, wherein at least some of the nodes are Optical Network Terminals (ONTs), and wherein the determining determines which ONTs are affected by the operating condition.

4. A method as set forth in claim 1, wherein the notification is provided over a same communication interface as that through which the service affected by the operating condition is provided.

5. A method as set forth in claim 1, wherein the communication services include at least a voice service, a data service, and a video service.

6. A method as set forth in claim 1, wherein the notification is provided by an Element Management System (EMS).

7. A method as set forth in claim 6, wherein the network includes one or more Optical Line Terminals (OLTs), and the EMS provides the notification to at least one of the OLTs.

8. A method as set forth in claim 7, wherein the network includes one or more Optical Network Terminals (ONTs), and the at least one OLT provides a further notification of the operating condition to at least one of the ONTs.

9. A method as set forth in claim 8, further comprising notifying a user of the operating condition.

10. A method as set forth in claim 1, further comprising requesting a status of a network operating condition.

11. A method as set forth in claim 1, further comprising providing troubleshooting information relating to the operating condition.

12. A method as set forth in claim 11, wherein the troubleshooting information is provided in one of a web page format, a video format, and an audible format.

13. A method as set forth in claim 12, wherein the troubleshooting information is provided in a user-interactive format.

14. A communication network, comprising:
at least one user communication terminal; and
a network element communicatively coupled in the network, and arranged to (i) detect an operating condition affecting any of plural communication services provided within the network, and (ii) automatically provide a notification of the operating condition to the at least one user communication terminal, by way of at least one of the communication services not affected by the operating condition.

15. A communication network as set forth in claim 14, wherein the network element also is arranged to determine which components of the network are affected by the operating condition.

16. A communication network as set forth in claim 15, wherein at least some of the components are Optical Network Terminals (ONTs).

17. A communication network as set forth in claim 14, wherein the communication services include at least a voice service, a data service, and a video service.

18. A communication network as set forth in claim 14, wherein the network element includes at least one of an Element Management System (EMS) and an Optical Network Terminal (ONT).

19. A communication network as set forth in claim 14, wherein the communication network further comprises one or more Optical Line Terminals (OLTs), and the network element provides the notification to the at least one user communication terminal via at least one of the OLTs.

20. A communication network as set forth in claim 14, wherein the network element also is arranged to provide at least one user-interactive interface providing troubleshooting information relating to the operating condition, accessible from the at least one user communication terminal.

21. A communication network as set forth in claim 14, further comprising at least one communication interface through which the communication services are provided to the at least one user communication terminal, wherein the notification is provided through the at least one communication interface.

22. A method for operating a communication network that supports a plurality of types of communication services, the program comprising:
detecting an operating condition affecting any of the communication services within the network; and
providing a notification of the operating condition, by way of at least one of the communication services not affected by the operating condition, and through a same interface as that through which the communication service affected by the operating condition is provided.
